(19) United States
(12) Patent Application Publication
(10) Pub. No.: US 2013/0037783 A1
(43) Pub. Date: Feb. 14, 2013

(54) ORGANIC LIGHT-EMITTING DISPLAY APPARATUS AND METHOD OF MANUFACTURING THE SAME

(71) Applicants: Yul-Kyu Lee, Yongin-city (KR); Sun Park, Yongin-city (KR)

(72) Inventors: Yul-Kyu Lee, Yongin-city (KR); Sun Park, Yongin-city (KR)

(73) Assignee: Samsung Mobile Display Co., Ltd., Yongin-city (KR)

(21) Appl. No.: 13/360,497

(22) Filed: Jan. 27, 2012

(30) Foreign Application Priority Data
Aug. 9, 2011 (KR) 10-2011-0079149

(51) Int. Cl. H01L 27/32; H01L 51/56

(52) U.S. Cl. 257/40; 438/23; 257/E27.119; 257/E51.018

(57) ABSTRACT

An organic light-emitting display apparatus is disclosed. In one aspect, the apparatus includes a thin film transistor comprising an active layer, a gate electrode, and source and drain electrodes. The apparatus also includes at least two capacitors each comprising a first electrode having a first region doped with ion impurities and a second region not doped with ion impurities, and formed on the same plane as the active layer. Each capacitor also includes a second electrode formed on the same plane as the gate electrode and disposed corresponding to the second region. The apparatus also includes a pixel electrode formed on the same plane as the gate electrode and connected to one of the source and drain electrodes, a light-emitting layer disposed on the pixel electrode, and an opposite electrode disposed on the light-emitting layer.

### CROSS-REFERENCE TO RELATED APPLICATIONS

This application claims the benefit of Korean Patent Application No. 10-2011-0079149, filed on Aug. 9, 2011, in the Korean Intellectual Property Office, the disclosure of which is incorporated herein in its entirety by reference.

### BACKGROUND

1. Field

The disclosed technology relates to an organic light-emitting display apparatus and a method of manufacturing the same.

2. Description of the Related Technology

Organic light-emitting display apparatuses can be manufactured as lightweight and thin apparatuses, and also have wide viewing angles, short response speeds, and low power consumption. Due to these advantages, they are getting attention as next generation display apparatuses.

### SUMMARY OF CERTAIN INVENTIVE ASPECTS

One inventive aspect is an organic light-emitting display apparatus including a thin film transistor including an active layer, a gate electrode, and source and drain electrodes. The apparatus also includes at least two capacitors each having a first electrode including a first region doped with ion impurities and a second region not doped with ion impurities, and formed in the same plane as the active layer of the thin film transistor. The capacitors also include a second electrode formed in the same plane as the gate electrode of the thin film transistor, where the boundary of the second electrode corresponds to the second region. The apparatus also includes a pixel electrode formed on the same plane as the gate electrode of the thin film transistor and connected to one of the source and drain electrodes, a light-emitting layer disposed on the pixel electrode, and an opposite electrode disposed on the light-emitting layer.

Another inventive aspect is a method of manufacturing an organic light-emitting display apparatus. The method includes performing a first mask process in which a semiconductor layer is formed on a substrate and the semiconductor layer is patterned to form an active layer of a thin film transistor and first electrodes of at least two capacitors. The method also includes performing a second mask process in which a first insulating layer is formed on the resultant structure of the first mask process, and a transparent conductive material and a first metal are sequentially deposited on the first insulating layer and patterned to form a gate electrode of the thin film transistor, second electrodes of the at least two capacitors, and a pixel electrode. The method also includes performing a third mask process in which a second insulating layer is formed on the resultant structure of the second mask process, and contact holes for exposing portions of source and the drain regions of the active layer and the pixel electrode are formed. The method also includes performing a fourth mask process in which a second metal is deposited on the resultant structure of the third mask process, and the second metal is patterned to form source and drain electrodes respectively contacting the source and the drain regions and to remove the first metal and the second metal on the pixel electrode. The method also includes performing a fifth mask process in which a third insulating layer is formed on the resultant structure of the fourth mask process, and the third insulating layer is patterned to expose the pixel electrode.

### BRIEF DESCRIPTION OF THE DRAWINGS

The above and other features and advantages are discussed below with reference to exemplary embodiments and to the attached drawings in which:

FIG. 1 is a schematic plan view of a pixel included in an organic light-emitting display apparatus according to an embodiment;

FIG. 2 is a circuit diagram of the organic light-emitting display apparatus of FIG. 1;

FIG. 3A is a cross-sectional view taken along a line A-A of FIG. 1;

FIG. 3B is a cross-sectional view taken along a line B-B of FIG. 1;

FIG. 4 is a schematic cross-sectional view illustrating a result of a first mask process performed on the organic light-emitting display apparatus of FIG. 1;

FIG. 5 is a schematic cross-sectional view illustrating a result of a second mask process performed on the organic light-emitting display apparatus of FIG. 1;

FIG. 6 is a schematic cross-sectional view illustrating a result of a third mask process performed on the organic light-emitting display apparatus of FIG. 1;

FIG. 7 is a schematic cross-sectional view illustrating a result of a fourth mask process performed on the organic light-emitting display apparatus of FIG. 1;

FIG. 8 is a schematic cross-sectional view illustrating a result of a fifth mask process performed on the organic light-emitting display apparatus of FIG. 1;

FIG. 9 is a schematic plan view of a pixel included in an organic light-emitting display apparatus according to another embodiment;

FIG. 10 is a circuit diagram of the organic light-emitting display apparatus of FIG. 9;

FIG. 11 is a schematic plan view of a pixel included in an organic light-emitting display apparatus according to another embodiment;

FIG. 12 is a circuit diagram of the organic light-emitting display apparatus of FIG. 11;

FIG. 13 is a schematic cross-sectional view of an organic light-emitting display apparatus as a comparative example; and

FIGS. 14 through 18 are schematic cross-sectional views for explaining a method of manufacturing an organic light-emitting display apparatus, as a comparative example.

### DETAILED DESCRIPTION OF CERTAIN INVENTIVE EMBODIMENTS

Hereinafter, various embodiments and aspects are described in detail with reference to the attached drawings.

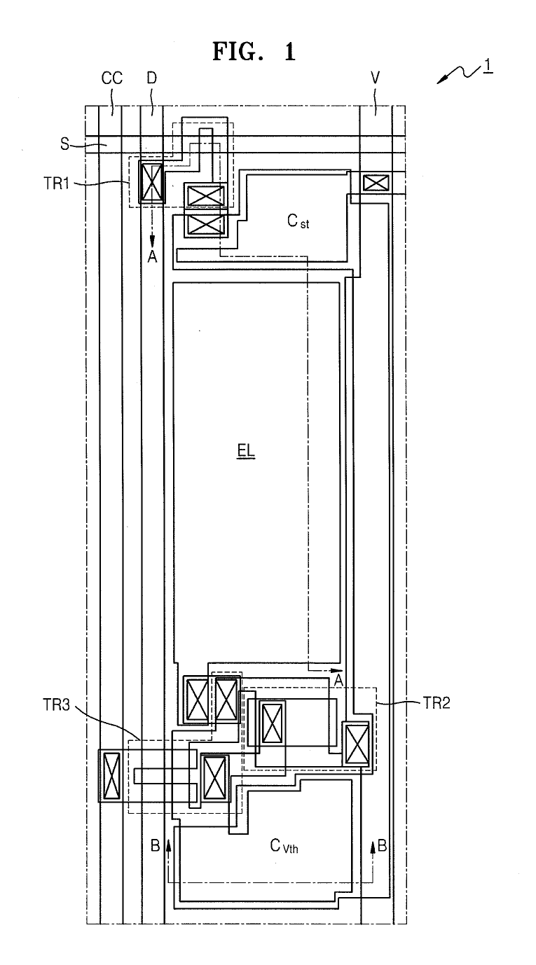

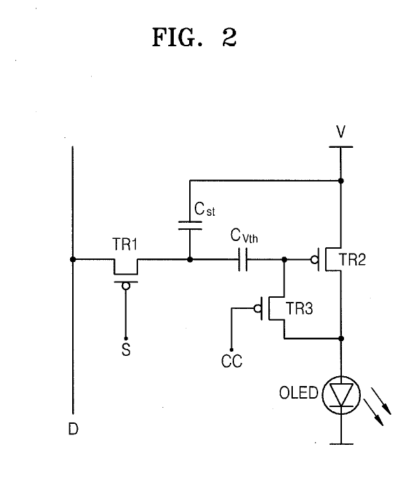

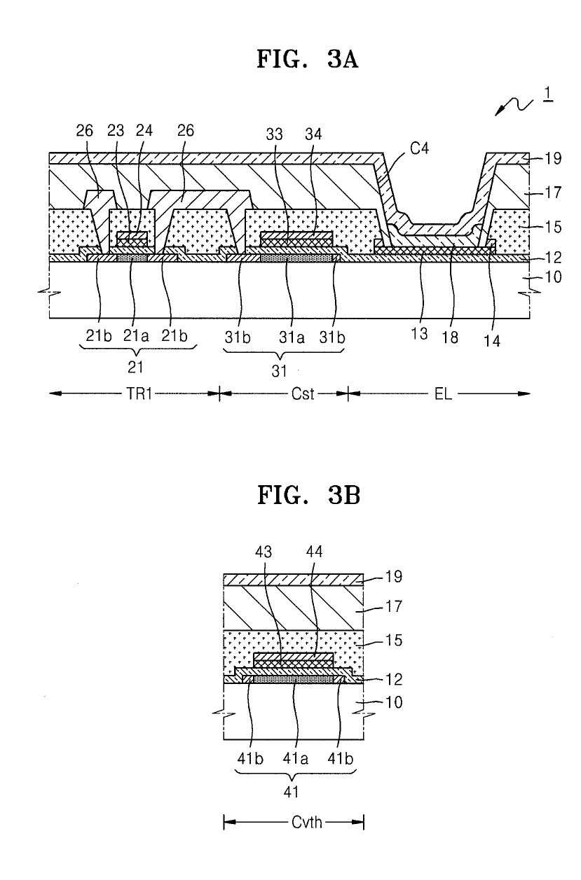

FIG. 1 is a schematic plan view of a pixel included in an organic light-emitting display apparatus 1 according to an embodiment, FIG. 2 is a circuit diagram of the organic light-emitting display apparatus of FIG. 1, FIG. 3A is a cross-sectional view taken along a line A-A of FIG. 1, and FIG. 3B is a cross-sectional view taken along a line B-B of FIG. 1.

Referring to FIG. 1, the pixel included in the organic light-emitting display apparatus 1 includes a plurality of conductive lines including a scan line S, a data line D, a power source voltage supply line V, and a compensation control signal line CC, a light-emitting region EL, first through third thin film transistors (TFTs) TR1, TR2, and TR3, a first capacitor Cst, and a second capacitor Cvth.

The organic light-emitting display apparatus of FIG. 1 is exemplary and the present invention is not limited thereto. That is, besides the conductive lines illustrated in FIG. 1, the organic light-emitting display apparatus may further include other conductive lines. Also, some of the conductive lines, for example, the compensation control signal line CC may not be included in each pixel. For example, adjacent pixels may share the same compensation control signal line CC. Also, the number of the TFTs and the number of the capacitors are not limited. For example, according to a pixel circuit unit, three or more TFTs and two or more capacitors may be used in combination.

Referring to FIGS. 1 and 2, a gate electrode of the first TFT TR1 is connected to the scan line S, a source electrode thereof is connected to the data line D, and a drain electrode thereof is connected to one electrode of the first capacitor Cst. A gate electrode of the second TFT TR2 is connected to one electrode of the second capacitor Cvth, a source electrode thereof is connected to the power source voltage supply line V, and a drain electrode thereof is connected to an anode of the light-emitting region EL. A gate electrode of the third TFT TR3 is connected to the compensation control signal line CC, a source electrode of the third TFT TR3 is connected to the gate electrode of the second TFT TR2, and a drain electrode of the third TFT TR3 is connected to the drain electrode of the second TFT TR2. In this regard, the first TFT TR1 acts as a switching transistor, the second TFT TR2 acts as a driving transistor, and the third TFT TR3 acts as a compensation transistor for compensating for a threshold voltage Vth. The first TFT TR1, the second TFT TR2, and the third TFT TR3 illustrated in FIG. 2 are P-type TFTs, but are not limited thereto. For example, at least one of the first TFT TR1, the second TFT TR2, and the third TFT TR3 may be an N-type TFT.

One electrode of the first capacitor Cst is connected to the power source voltage supply line V, and the other electrode thereof is connected to the drain electrode of the first TFT TR1. One electrode of the second capacitor Cvth is connected to the gate electrode of the second TFT TR2, and the other electrode thereof is connected to the drain electrode of the first TFT TR1. The electrode of the first capacitor Cst and the electrode of the second capacitor Cvth that are connected to the drain electrode of the first TFT TR1 are electrically connected to each other. In this regard, the first capacitor Cst may act as a storage capacitor for storing data signals when the data signals are applied to the first TFT TR1, and the second capacitor Cvth may act as a compensation capacitor for compensating for variation of a threshold voltage Vth.

Referring to FIG. 3A, the first TFT TR1 is disposed on the substrate 10. The first TFT TR1 includes an active layer 21 disposed on the substrate 10, gate electrodes 23 and 24, and source and drain electrodes 26. FIG. 3A illustrates a cross-section of only the first TFT TR1, and the second TFT TR2 and the third TFT TR3 have similar cross sections as the first TFT TR1.

The substrate 10 may be formed of various materials, for example, glass or plastic. If the organic light-emitting display apparatus 1 of the present embodiment is a bottom emission type display apparatus and an image is formed toward the substrate 10, the substrate 10 may be formed of a transparent material.

Although not illustrated in FIG. 3A, a buffer layer (not shown) may be further formed on the substrate 10 to form an even surface and to prevent permeation of impurity elements into layers above the substrate 10. The buffer layer may include SiO₂ and/or SiNx.

The active layer 21 may be formed of amorphous silicon or cystalline silicon, and may include a channel region 21a not doped with ion impurities, and source and drain regions 21b doped with ion impurities disposed outside the channel region 211c. The source and drain regions 21b may include, for example, a p-type semiconductor formed by doping with a Group 3 element or an n-type semiconductor formed by doping with a Group 5 element.

A first insulating layer 12 that functions as a gate insulation layer is disposed on the active layer 21. The first insulating layer 12 may be formed as one or more inorganic layer formed of SiNx and/or SiO₂.

The gate electrodes 23 and 24 are disposed corresponding to the channel region 21 a of the first insulating layer 12. The gate electrodes 23 and 24 include the first layer 23 formed of a transparent conductive material and the second layer 24 formed of a low resistant metal and disposed above the first layer 23. The gate electrodes 23 and 24 may include conductive materials having different etching selectivities. For example, the first layer 23 may include a transparent conductive material including at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). The second layer 24 may include at least one material selected from the group consisting of Ti, Mo, Al, Ag, Cu, and an alloy thereof.

A second insulating layer 15 may be disposed on the gate electrodes 23 and 24. The second insulating layer 15 may act as an interlayer insulating layer for insulating the gate electrodes 23 and 24 from the source and drain electrodes 26. The second insulating layer 15 may be formed of various insulating materials. For example, the second insulating layer 15 may be formed of an organic material or an inorganic material, such as an oxide or a nitride. An inorganic material for forming the second insulating layer 15 may include SiO₂, SiNx, SiON, Al₂O₃, TiO₂, Ta₂O₅, HfO₂, ZrO₂, BST, or PZT, and an organic material for forming the second insulating layer 15 may include a generally available polymer, such as PMMA or PS, a polymer derivative having a phenol group, an acryl-based polymer, an imide-based polymer, an aryl ether-based polymer, an amide-based polymer, a fluorine-based polymer, p-xylene-based polymer, a vinyl alcohol-based polymer, or a blend thereof Also, the second insulating layer 15 may have a composite stack including an inorganic insulating layer and an organic insulating layer.

The source and drain electrodes 26 are disposed on the second insulating layer 15. The source and drain electrodes 26 are connected to the source and drain regions 21b of the active layer 21.

The first capacitor Cst is disposed on the substrate 10. The first capacitor Cst includes a first electrode 31 that is formed in the same plane as the active layer 21, and second electrodes 33 and 34 that are formed in the same plane as the gate electrodes 23 and 24. The first electrode 31 may be formed with the same layer as the active layer 21, and the second electrodes 33 and 34 may be formed with the same layers as the gate electrodes 23 and 24.

The first layer 31 may include a part 31 a not doped with ion impurities and a part 31b doped with ion impurities. The part 31b doped with ion impurities is disposed to surround the part 31a not doped with ion impurities. Ion impurities may be formed as a p-type semiconductor by doping with a Group 3 element or an n-type semiconductor formed by doping with a Group 5 element.

The part 31a not doped with ion impurities may be formed as the same amorphous semiconductor or poly semiconductor as the channel region 21a of the active layer 21. The part 31b doped with ion impurities may be formed as the same amorphous semiconductor or poly semiconductor as the source and drain region 21b of the active layer 21. The perimeter of the first electrode 31 is doped with ion impurities in the present embodiment, and thus dropping a voltage applied to the first capacitor Cst compared to a structure having no region doped with ion impurities.

The first insulating layer 12 is formed on the first electrode 31 and functions as a dielectric layer of the first capacitor Cst.

The second electrodes 33 and 34 are disposed on the first insulating layer 12. The second electrodes 33 and 34 include the first layer 33 formed of the same transparent conductive material as the first layer 23 of the gate electrodes, and the second layer 34 formed of the same metal as the second layer 24 of the gate electrodes.

The second electrodes 33 and 34 are disposed corresponding to the part 31a not doped with ion impurities of the first layer 31. Sizes of the second electrodes 33 and 34 are materially the same as a size of the part 31a not doped with ion impurities of the first layer 31. As will be described later, if the first layer 31 is doped with ions, the second electrodes 33 and 34 function as a doping block mask.

The light-emitting region EL is disposed on the substrate 10. The light-emitting region EL includes a pixel electrode 13, a light-emitting layer 18, and an opposite electrode 19.

A second insulating layer 15 is formed on the boundary of the pixel electrode 13. A third insulating layer 17 is formed on the second insulating layer 15. The third insulating layer 17 has a fourth contact hole C4 exposing a top portion of the pixel electrode 13. The light-emitting layer 18 is disposed in the fourth contact hole C4. In this embodiment, light-emitting layer 18 determines the light-emitting region EL.

The light-emitting layer 18 may, for example, include a low molecular weight organic material or a polymer organic material. If the light-emitting layer 18 includes a low molecular weight organic material, a hole transport layer (HTL), a hole injection layer (HIL), an electron transport layer (ETL), and an electron injection layer (EIL) may be formed near the light-emitting layer 18. Also, various other layers may be further formed near the light-emitting layer 18 as required. In this case, the low molecular weight organic material may be copper phthalocyanine (CuPc), N′-Di(naphthalene-1-yl)-N, N′-diphenyl-benzidine (NPB), or tris-8-hydroxyquinoline aluminum (Alq3). Also, if the light-emitting layer 18 includes a polymer organic material, a HTL may be formed near the light-emitting layer 18. The HTL may include poly-(3,4)-ethylene-dihydroxy thiophene (PEDOT) or polyaniline (PANI). In this case, the polymer organic material for forming the light-emitting layer 18 may be a poly-phenylenevinylene (PPV)-based material or a polyfluorene-based material. The light-emitting layer 18 may further include inorganic materials in addition to the above organic materials.

The opposite electrode 19 is deposited on the light-emitting layer 18 as a common electrode for all pixels. In the organic light-emitting display apparatus 1 according to the present embodiment, the pixel electrode 13 is used as an anode and the opposite electrode 19 is used as a cathode. However, in another embodiment, the pixel electrode 13 is used as a cathode and the opposite electrode 19 is used as an anode.

The opposite electrode 19 may be a reflective electrode including a reflective material. In this case, the opposite electrode 19 may include at least one material selected from the group consisting of Al, Mg, Li, Ca, LiF/Ca, and LiF/Al. Since the opposite electrode 19 is a reflective electrode, light emitted from the light-emitting layer 18 is reflected by the opposite electrode 19 and the reflected light is emitted toward the substrate 10 through the pixel electrode 13 formed of a transparent conductive material.

Referring to FIG. 3B, the second capacitor Cvth is disposed on the substrate 10. The second capacitor Cvth includes a first electrode 41 that is formed on the same plane as the active layer 21, and second electrodes 43 and 44 that are formed on the same plane as the gate electrodes 23 and 24. The first electrode 41 may be formed with the same layer as the active layer 21, and the second electrodes 43 and 44 may be formed with the same layers as the gate electrodes 23 and 24.

The first layer 41 may include a part 41a not doped with ion impurities and a part 41b doped with ion impurities. The part 41b doped with ion impurities is disposed to surround the part 41a not doped with ion impurities. Ion impurities may be formed as a p-type semiconductor by doping with a Group 3 element or an n-type semiconductor formed by doping with a Group 5 element. However, the part 31b doped with ion impurities of the first capacitor Cst and the part 41b doped with ion impurities of the second capacitor Cvth are doped with the same type of ion impurities.

The part 41a not doped with ion impurities may be formed as the same amorphous semiconductor or poly semiconductor as the channel region 21a of the active layer 21. The part 41b doped with ion impurities may be formed as the same amorphous semiconductor or poly semiconductor as the source and drain region 21b of the active layer 21. The boundary of the first electrode 41 is doped with ion impurities in the present embodiment, and thus dropping a voltage applied to the second capacitor Cvth compared to a structure having no region doped with ion impurities.

The first insulating layer 12 is formed on the first electrode 41. The second electrodes 43 and 44 are disposed on the first insulating layer 12. The second electrodes 43 and 44 include the first layer 43 formed of the same transparent conductive material as the first layer 23 of the gate electrodes, and the second layer 44 formed of the same metal as the second layer 24 of the gate electrodes.

The second electrodes 43 and 44 are disposed corresponding to the part 41 a not doped with ion impurities of the first layer 41. Sizes of the second electrodes 43 and 44 are materially the same as a size of the part 41a not doped with ion impurities of the first layer 41. As will be described later, when the first layer 41 is doped with ions, the second electrodes 43 and 44 function as a doping block mask.

Referring to FIGS. 3A and 3B, the organic light-emitting display apparatus 1 according to the present embodiment includes at least two capacitors Cst and Cvth including the first electrodes 31 and 41 whose boundaries having the parts 31b an 41b doped with ion impurities, thereby dropping voltages applied to the capacitors Cst and Cvth compared to a structure having no region doped with ion impurities. In addition, the organic light-emitting display apparatus 1 allows a constant electrostatic capacitance to be maintained within a wider voltage range than the structure having no region doped with ion impurities. Thus, the structure having no region doped with ion impurities may improve a voltage margin when a circuit is constructed.

Meanwhile, referring to FIGS. 1 and 2, the first electrodes 31 and 41 of the capacitors Cst and Cvth are electrically connected to each other, and, in particular, are electrically connected between the parts 31b an 41b doped with ion impurities of the boundaries of the first electrodes 31 and 41, whereas, the second electrodes 33, 34, 43, and 44 of the capacitors Cst and Cvth are electrically separated from each other.

Although the first capacitor Cst and the second capacitor Cvth are separated from each other and are disposed above and below the light-emitting region EL in FIG. 1, this is merely exemplary. The organic light-emitting display apparatus 1 according to the present embodiment is not limited to the shown positions of capacitors. For example, one of the first capacitor Cst and the second capacitor Cvth or both of them may be disposed between the light-emitting region EL and the power source voltage supply line V, and a portion of the first capacitor Cst and the second capacitor Cvth and the power source voltage supply line V may overlap.

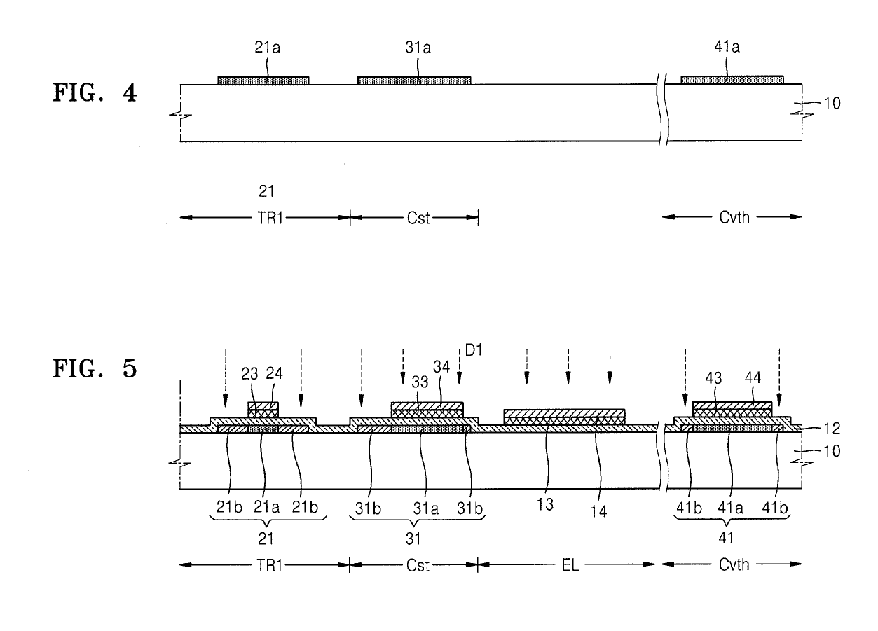

Hereinafter, a method of manufacturing the organic light-emitting display apparatus 1 according to an embodiment is described in detail with reference to FIGS. 4 through 8.

FIG. 4 is a schematic cross-sectional view illustrating a result of a first mask process performed on the organic light-emitting display apparatus 1. Referring to FIG. 4, the active layer 21a of the first TFT TR1, the first electrode 31a of the first capacitor Cst, and the first electrode 41a of the second capacitor Cvth are formed on the substrate 10.

Although not illustrated in FIG. 4, a semiconductor layer (not shown) is deposited on the substrate 10, and a photoresist (not shown) is coated on the semiconductor layer. By performing a photolithography process using a first photo mask (not shown), the semiconductor layer is patterned to simultaneously form the active layer 21a of the first TFT TR1, the first electrode 31a of the first capacitor Cst, and the first electrode 41a of the second capacitor Cvth. Although not illustrated in FIG. 4, the second TFT TR2 and the third TFT TR3 may be formed by using the same method as used to form the first TFT TR1.

In the first mask process performed by photolithography, the first photo mask is exposed to light emitted from an exposure device (not shown) and then, a series of processes including developing, etching, and stripping or ashing are performed thereon.

The active layer 21a may include amorphous silicon or polysilicon. Also, the active layer 21a may be formed by crystallizing polysilicon into amorphous silicon. The crystallizing of amorphous silicon may be performed by, for example, rapid thermal annealing (RTA), solid phase crystallization (SPC), excimer laser annealing (ELA), metal induced crystallization (MIC), metal induced lateral crystallization (MILC), or sequential lateral solidification (SLS).

FIG. 5 is a schematic cross-sectional view illustrating a result of a second mask process performed on the organic light-emitting display apparatus 1. Referring to FIG. 5, the first insulating layer 12 is deposited on the resultant structure of the first mask process illustrated in FIG. 4, and the gate electrodes 23 and 24, the second electrodes 33 and 34 of the first capacitor Cts, and the second electrodes 43 and 44 of the second capacitor Cvth, and the pixel electrodes 13 and 14 are sequentially deposited on the first insulating layer 12.

The first layer 23 of the gate electrodes, the first layer 33 of the second electrode of the first capacitor Cst, the first layer 43 of the second electrode of the second capacitor Cvth, and the first layer 13 of the pixel electrodes may be simultaneously formed on the same plane, and may be formed of the same transparent conductive material selected from the group consisting of ITO, IZO, ZnO, and In₂O₃.

The second layer 24 of the gate electrodes, the second layer 34 of the second electrode of the first capacitor Cst, the second layer 44 of the second electrode of the second capacitor Cvth, and the second layer 14 of the pixel electrodes may be simultaneously formed on the same plane, and may be formed of at least one selected from the group consisting of Ti, Mo, Al, Ag, Cu, and alloys thereof.

An ion impurity is doped on the resultant structures (D1). The ion impurity used for doping may be an ion of a Group 3 element and a Group 5 element, and a concentration of the ion impurity may be equal to or greater than 1×¹⁵ atoms/cm² and the doping may be performed on the active layer 21 and the first electrodes 31 and 41 of a TFT.

The active layer 21 includes the source and drain regions 21b doped with ion impurities and the channel region 21a not doped with ion impurities and interposed between the source and drain regions 21b. That is, the gate electrodes 23 and 24 are used as a self aligning mask, and thus, the source and drain regions 21b may be formed without use of a separate photo mask.

Sizes of the second electrodes 33 and 34 of the first capacitor Cst and the second electrodes 43 and 44 of the second capacitor Cvth are smaller than those of the first electrodes 31 and 41. The first electrodes 31 and 41 of the first capacitor Cst and the second capacitor Cvth include the regions 31a and 41a not doped with ion impurities and the regions 31b and 41b doped with ion impurities at positions corresponding to the second electrodes 33, 34, 43, and 44, respectively. That is, the gate electrodes 33, 34, 43, and 44 are used as a self aligning mask, and thus, the regions 31b and 41b doped with ion impurities may be formed without use of a separate photo mask.

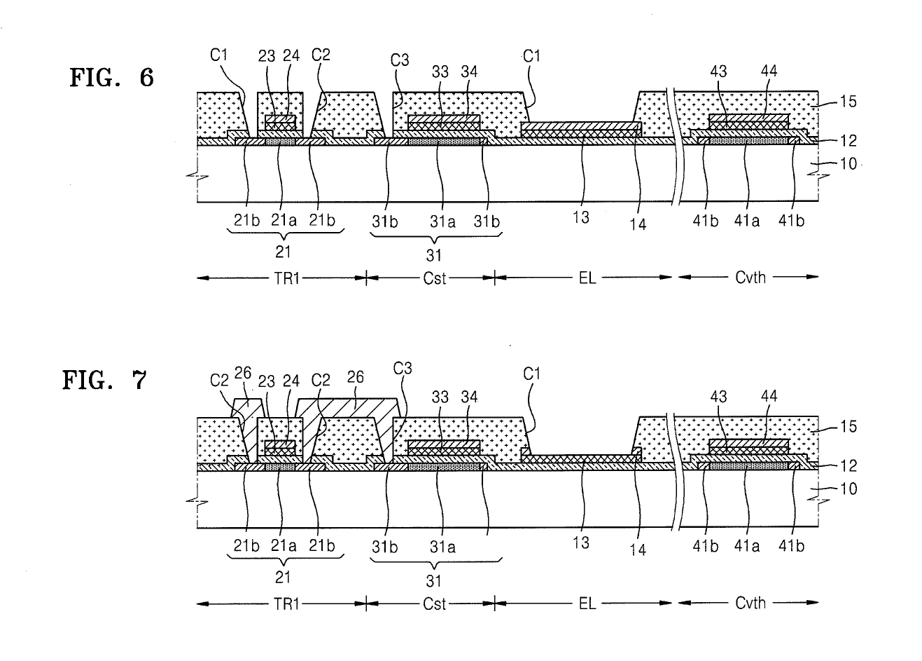

FIG. 6 is a schematic cross-sectional view illustrating a result of a third mask process performed on the organic light-emitting display apparatus 1. Referring to FIG. 6, the second insulating layer 15 is deposited on the resultant structure of the second mask process of FIG. 5, and the second insulating layer 15 is patterned to form a first contact hole C1 exposing an upper surface of the second layer 14 of the pixel electrodes, a second contact hole C2 exposing portions of the source and drain regions 21a of the active layer 21, a third contact hole C3 exposing a portion of the first electrode 31b of the first capacitor Cst.

FIG. 7 is a schematic cross-sectional view illustrating a result of a fourth mask process performed on the organic light-emitting display apparatus 1. Referring to FIG. 7, the source and drain electrodes 26 respectively contacting the source and drain regions 21b through the second contact hole C2 are formed on the resultant structure of the third mask process illustrated in FIG. 6, the drain electrode 26 of the first TFT TR1 and the first electrode 31b of the first capacitor Cst are electrically connected to each other through the third contact hole C3, and a portion of the second layer 14 of the pixel electrodes of the light-emitting region EL is removed.

The fourth mask process may include a first etching process and a second etching process following the first etching process. In the first etching process, a conductive material for forming the source and drain electrodes 26 deposited on the second layer 14 of the pixel electrodes is etched. In the second etching process, the second layer 14 of the pixel electrodes is removed. Such separation of an etching process may be required when a material for forming the second layer 14 of the pixel electrodes is different from a material for forming the source and drain electrodes 26. If the material for forming the second layer 14 of the pixel electrodes and the material for forming the source and drain electrodes 216 are the same, one etching process is possible.

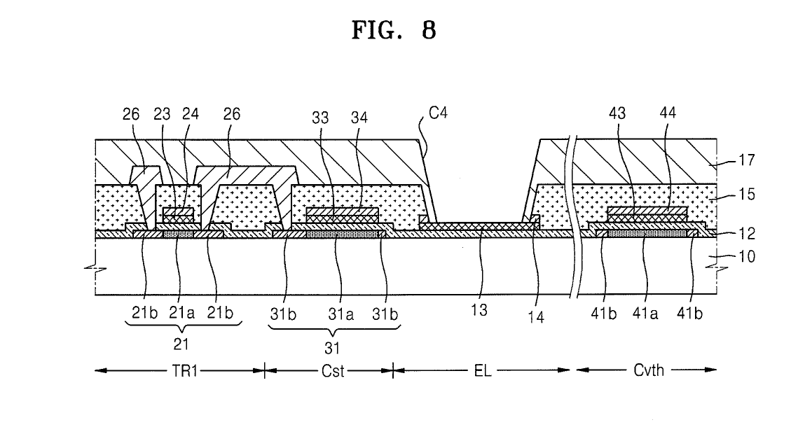

FIG. 8 is a schematic cross-sectional view illustrating a result of a fifth mask process performed on the organic light-emitting display apparatus 1. Referring to FIG. 8, the third insulating layer 17 is formed on the resultant structures of the fourth mask process illustrated in FIG. 7, and a contact hole C4 exposing an upper surface of the first layer 13 of the pixel electrodes is formed.

The light-emitting layer 18 (see FIG. 3A) is formed inside the contact hole C4, and when a voltage is applied to the light-emitting layer 18 by the first layer 13 of the pixel electrodes and the opposite electrode 19 (see FIG. 3A), the light-emitting layer 18 emits light.

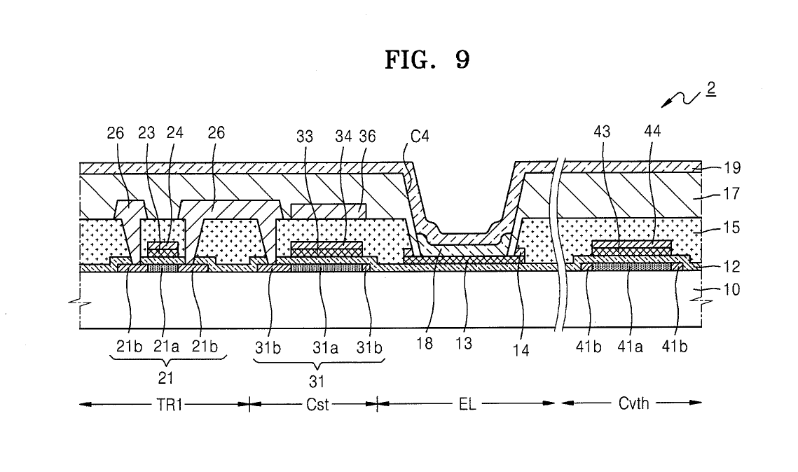

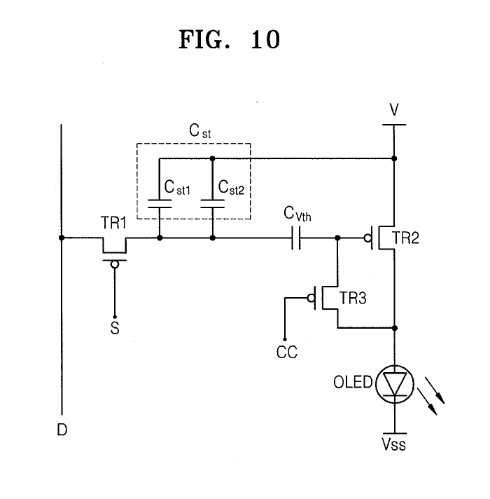

FIG. 9 is a schematic plan view of a pixel included in an organic light-emitting display apparatus 2 according to another embodiment. FIG. 10 is a circuit diagram of the organic light-emitting display apparatus 2 of FIG. 9.

The differences between the organic light-emitting display apparatus 2 of the present embodiment and the organic light-emitting display apparatus 1 described with reference to FIG. 1 will now be described below.

Referring to FIG. 9, the organic light-emitting display apparatus 2 includes the light-emitting region EL, the first TFT TR1, the first capacitor Cst, and the second capacitor Cvth on the substrate 10. The second and third TFT TR2 and TR3 are omitted here.

The structures of the light-emitting region EL, the first TFT TR1, and the second capacitor Cvth are the same as those described with reference to FIG. 1, except that the first capacitor Cst includes the second insulating layer 15 formed on the second electrodes 33 and 34, and the third electrode 36 including the same material as the source and drain electrodes 26 formed on the second insulating layer 15.

Although not shown in FIG. 9, the third electrode 36 and the first electrode 31 are electrically connected to each other in FIG. 10. Thus, the first capacitor Cst is connected in parallel to a first electrostatic capacitor Cst1 formed between the first electrode 31 and the second electrodes 33 and 34, and a second electrostatic capacitor Cst2 formed between the second electrodes 33 and 34 and the third electrode 36, thereby increasing the whole electrostatic capacitance of the first capacitor Cst.

Meanwhile, although the third electrode 36 is formed in the first capacitor Cst in FIGS. 9 and 10, embodiments are not limited thereto. The third electrode 36 is formed in the second capacitor Cvth, which may increase the electrostatic capacitance of the second capacitor Cvth.

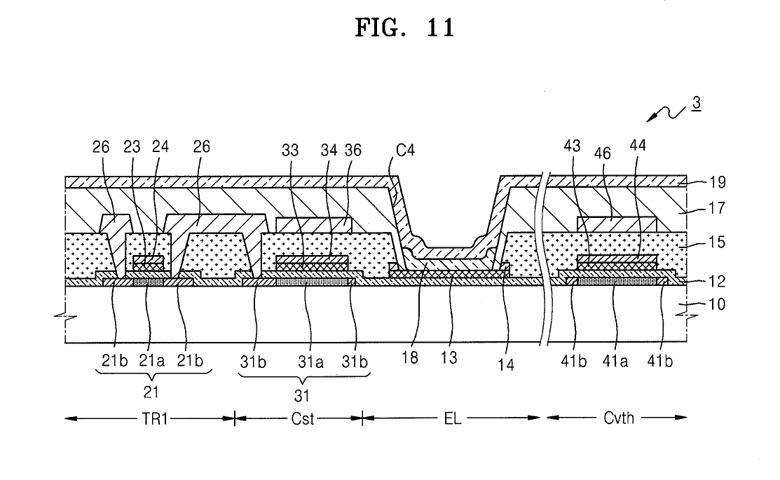

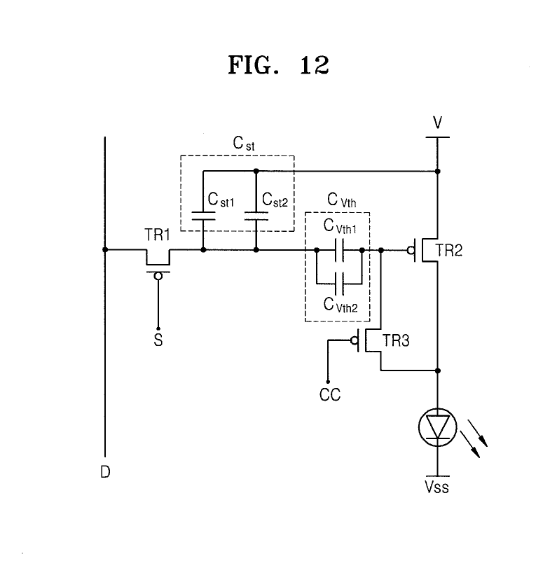

FIG. 11 is a schematic plan view of a pixel included in an organic light-emitting display apparatus 3 according to another embodiment. FIG. 12 is a circuit diagram of the organic light-emitting display apparatus 3 of FIG. 11.

The differences between the organic light-emitting display apparatus 2 of the present embodiment and the organic light-emitting display apparatus 1 described with reference to FIG. 1 will now be described below.

Referring to FIG. 11, the organic light-emitting display apparatus 3 includes the light-emitting region EL, the first TFT TR1, the first capacitor Cst, and the second capacitor Cvth on the substrate 10. The second and third TFT TR2 and TR3 are omitted here.

The structures of the light-emitting region EL, the first TFT TR1, and the second capacitor Cvth are the same as those described with reference to FIG. 1, except that the first capacitor Cst and the second capacitor Cvth include the third electrodes 36 and 46. The third electrodes 36 and 46 are formed on the second insulating layer 15 and include the same material as the source and drain electrodes 26. The third electrodes 36 and 46 may overlap the power source voltage supply line V. The power source voltage supply line V generally has a relatively greater width than the scan line S or the data line D, and is formed of a metal having a high reflectivity or a low transmittance. Thus, the third electrodes 36 and 46 of the first capacitor Cst and the second capacitor Cvth overlap the power source voltage supply line V, thereby reducing an area of capacitors and increasing an aperture ratio of the organic light-emitting display apparatus 3.

Meanwhile, although not shown in FIG. 11, the third electrode 36 and the first electrode 31 of the first capacitor Cst are electrically connected to each other in FIG. 12. Thus, the first capacitor Cst is connected in parallel to the first electrostatic capacitor Cst1 formed between the first electrode 31 and the second electrodes 33 and 34, and the second electrostatic capacitor Cst2 formed between the second electrodes 33 and 34 and the third electrode 36, thereby increasing the whole electrostatic capacitance of the first capacitor Cst.

Referring to FIG. 12, the third electrode 46 and the first electrode 41 of the second capacitor Cvth are electrically connected to each other. Thus, the second capacitor Cvth is connected in parallel to a first electrostatic capacitor Cvth1 formed between the first electrode 41 and the second electrodes 43 and 44, and a second electrostatic capacitor Cvth2 formed between the second electrodes 43 and 44 and the third electrode 46, thereby increasing the electrostatic capacitance of the second capacitor Cvth.

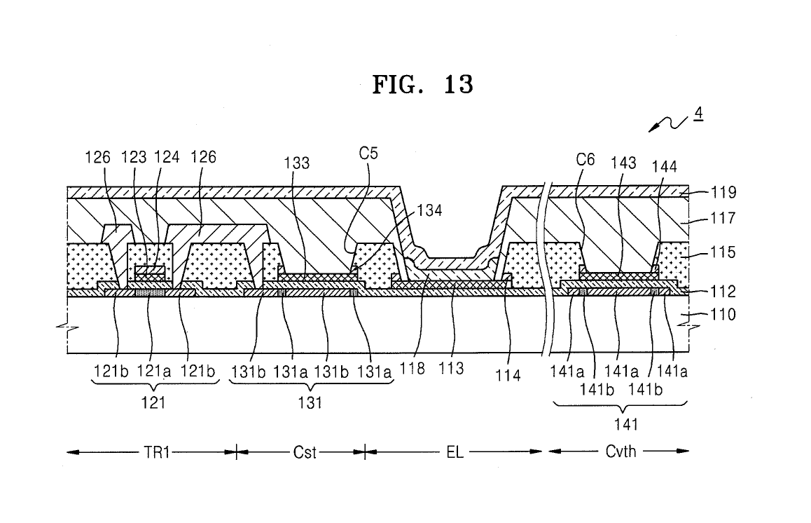

Hereinafter, a method of manufacturing the organic light-emitting display apparatus 4 as a comparative example will be described in detail with reference to FIGS. 13 through 18.

FIG. 13 is a schematic cross-sectional view of the organic light-emitting display apparatus 4 as a comparative example. Referring to FIG. 13, the organic light-emitting display apparatus 4 includes the light-emitting region EL, the first TFT TR1, the first capacitor Cst, and the second capacitor Cvth on the substrate 10. The second and third TFT TR2 and TR3 are omitted here.

The structures of the light-emitting region EL and the first TFT TR1 are the same as those described with reference to FIG. 1 but the structures of the first capacitor Cst and the second capacitor Cvth are different from those described with reference to FIG. 1. In more detail, doping distributions of first electrodes 131 and 141 of the first capacitor Cst and the second capacitor Cvth are different from those described with reference to FIG. 1.

The first electrode 131 of the first capacitor Cst includes regions 131b doped with ion impurities corresponding to a second electrode 133. The first electrode 141 of the second capacitor Cvth regions 141b doped with ion impurities corresponding to a second electrode 143.

Meanwhile, an end portion of a second layer 134 of the second electrode 133 of the first capacitor Cst is covered by the second insulating layer 15, and a center portion thereof is removed. An end portion of a second layer 144 of the second electrode 143 of the second capacitor Cvth is covered by the second insulating layer 15, and a center portion thereof is removed.

The first electrodes 131 and 141 corresponding to the second layer 134 of the second electrode of the first capacitor Cst and the second layer 144 of the second electrode of the second capacitor Cvth having end portions covered by the second insulating layer 15 include regions 131a and 141a not doped with ion impurities.

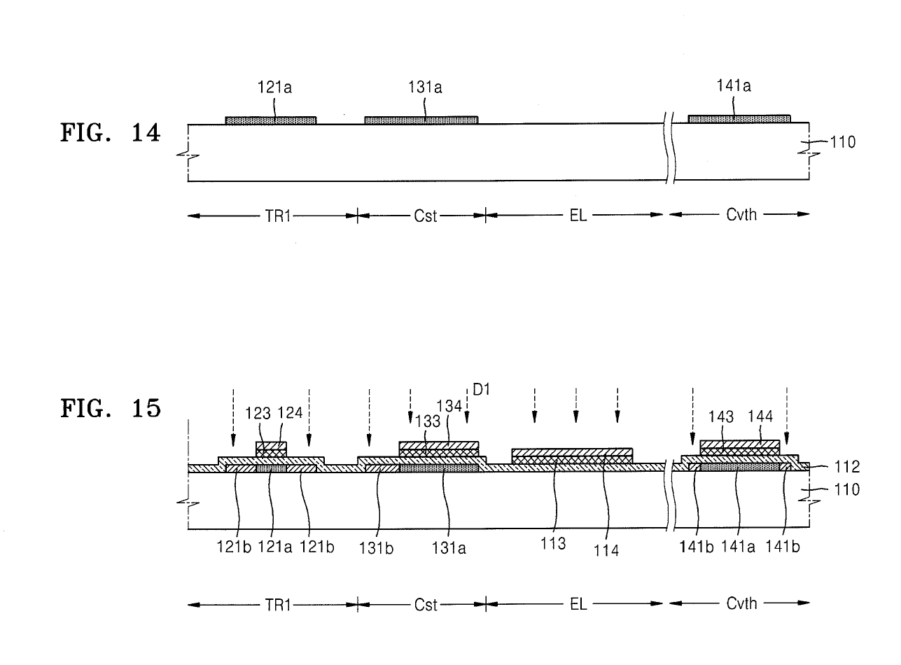

FIG. 14 is a schematic cross-sectional view illustrating a result of a first mask process performed on the organic light-emitting display apparatus 4 as a comparative example. As described above, an active layer 121a of the first TFT TR1, a first electrode 131a of the first capacitor Cst, and a first electrode 141a of the second capacitor Cvth are formed on the substrate 10. FIG. 15 is a schematic cross-sectional view illustrating a result of a second mask process performed on the organic light-emitting display apparatus 4 as a comparative example.

As described in FIG. 5, the first insulating layer 12 is deposited on the resultant structure of the first mask process illustrated in FIG. 14, and gate electrodes 123 and 124, second electrodes 133 and 134 of the first capacitor Cts, and second electrodes 143 and 144 of the second capacitor Cvth, and pixel electrodes 113 and 114 are sequentially deposited on the first insulating layer 12.

Following the first mask process, the resultant structure (D1) is doped with ion impurities. As described above, ion impurities used for doping may be ions of a Group 3 element and a Group 5 element, and a concentration of the ion impurities may be equal to or greater than 1×10¹⁵ atoms/cm² and the doping may be performed on the active layer 121a of the first TFT TR1, the first electrode 131a of the first capacitor Cst, and the first electrode 141a of the second capacitor Cvth.

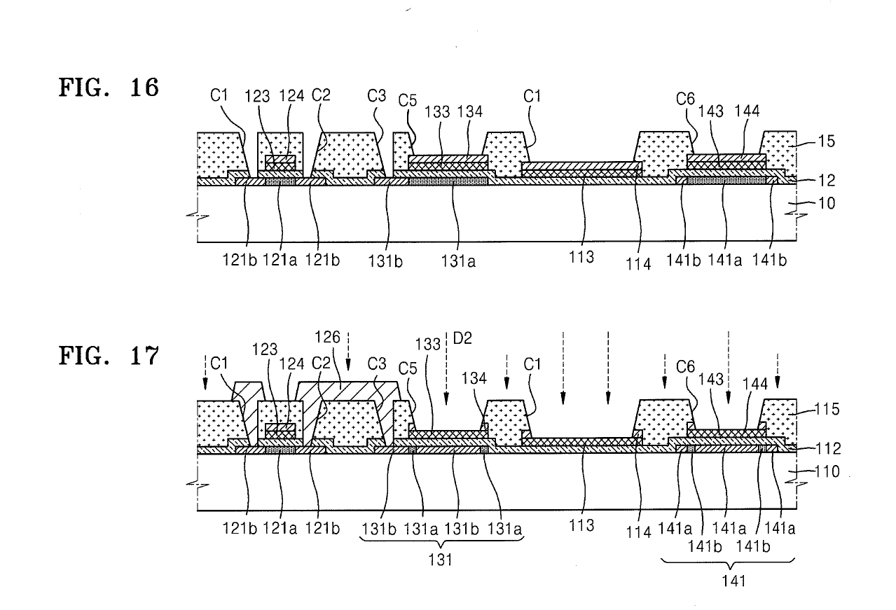

FIG. 16 is a schematic cross-sectional view illustrating a result of a third mask process performed on the organic light-emitting display apparatus 4 as a comparative example. Referring to FIG. 16, the second insulating layer 15 is deposited on the resultant structure of the second mask process illustrated in FIG. 15, and the second insulating layer 15 is patterned to form the first contact hole C1 exposing an upper surface of the second layer 114 of the pixel electrodes, the second contact hole C2 exposing portions of source and drain regions 121b of the active layer 121a, the third contact hole C3 exposing a portion of the first electrode 131b of the first capacitor Cst, a fifth contact hole C5 exposing a portion of the second layer 134 of the second electrodes of the first capacitor Cst, and a contact hole C6 exposing a portion of the second layer 144 of the second electrodes of the second capacitor Cvth.

FIG. 17 is a schematic cross-sectional view illustrating a result of a fourth mask process performed on the organic light-emitting display apparatus 4 as a comparative example. Referring to FIG. 17, source and drain electrodes 126 respectively contacting the source and drain regions 121b through the second contact hole C2 are formed on the resultant structure of the third mask process illustrated in FIG. 16, the drain electrode 126 of the first TFT TR1 and the first electrode 131b of the first capacitor Cst are electrically connected to each other through the third contact hole C3, and a portion of the second layer 134 of the second electrodes of the first capacitor Cst, the second layer 144 of the second electrodes of the second capacitor Cvth, and the second layer 114 of the pixel electrodes of the light-emitting region EL are removed.

Following the fourth mask process, the resultant structure (D2) is doped with ion impurities. As described above, ion impurities used for doping may be ions of a Group 3 element and a Group 5 element, and a concentration of the ion impurities may be equal to or greater than 1×10¹⁵ atoms/cm² and the doping may be performed on the center of the first electrodes 131 and 141 of the first capacitor Cst and the second capacitor Cvth.

Since the first layers 133 and 143 of the second electrodes of the first capacitor Cst and the second capacitor Cvth have a thickness of 1000 Å or less, ion impurities may pass through the first layers 133 and 143 and may be doped on the first electrodes 131b and 141b. However, the first electrodes 131 and 141 corresponding to the second layer 134 of the second electrode of the first capacitor Cst and the second layer 144 of the second electrode of the second capacitor Cvth having end portions covered by the second insulating layer 15 include the regions 131a and 141a not doped with ion impurities. Thus, although doping is performed twice, an obstacle occurs in reducing voltages applied to the first capacitor Cst and the second capacitor Cvth.

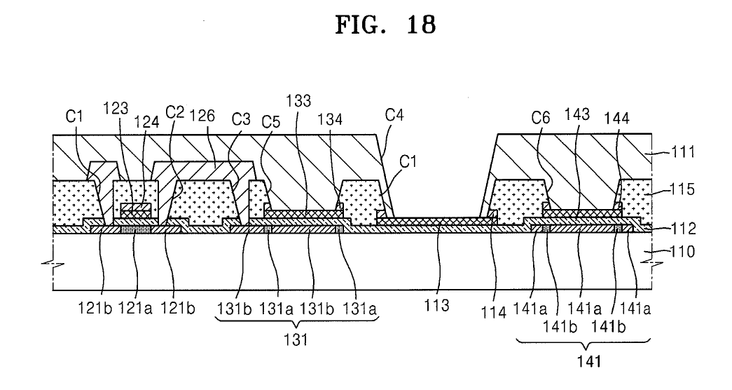

FIG. 18 is a schematic cross-sectional view illustrating a result of a fifth mask process performed on the organic light-emitting display apparatus 4 as a comparative example. Referring to FIG. 18, the third insulating layer 17 is formed on the resultant structures of the fourth mask process illustrated in FIG. 17, and the contact hole C4 exposing an upper surface of the first layer 113 of the pixel electrodes is formed. A light-emitting layer 118 (see FIG. 3A) is formed inside the contact hole C4, and when a voltage is applied to the light-emitting layer 118 by the first layer 113 of the pixel electrodes and an opposite electrode 119 (see FIG. 3A), the light-emitting layer 118 emits light.

Therefore, the organic light-emitting display apparatuses 1 through 3 according to the embodiments have one doping operation, thereby simplifying a manufacturing process and reducing manufacturing expense, compared to the organic light-emitting display apparatus 4 as a comparative example.

An organic light-emitting display apparatus and a method of manufacturing the same, according to the above embodiments provide at least the following effects.

First, a doping process is reduced to one time, and thus a manufacturing process may be simplified and manufacturing expense may be reduced. Second, an upper electrode of a capacitor is greater than a lower electrode thereof, and doping regions are formed in the boundary and wiring of the lower electrode, and thus, a voltage design margin may be improved, in spite of a MOS CAP. Third, capacitors are connected in parallel and thus, the entire electrostatic capacitance may be improved. Fourth, an organic light-emitting display apparatus having the above effects may be manufactured by performing a mask process five times.

While certain features have been particularly shown and described with reference to exemplary embodiments, it will be understood by those of ordinary skill in the art that various changes in form and details may be made therein.

What is claimed is:

1. An organic light-emitting display apparatus comprising:
a thin film transistor comprising an active layer, a gate electrode, and source and drain electrodes;
a plurality of capacitors each comprising:
a first electrode comprising a first region doped with ion impurities and a second region not doped with ion impurities, and formed in substantially the same plane as the active layer of the thin film transistor, and
a second electrode formed in substantially the same plane as the gate electrode of the thin film transistor, wherein the boundary of the second electrode corresponds to the second region;
a pixel electrode formed in substantially the same plane as the gate electrode of the thin film transistor and connected to one of the source and drain electrodes;
a light-emitting layer disposed on the pixel electrode; and
an opposite electrode disposed on the light-emitting layer.

2. The organic light-emitting display apparatus of claim 1, wherein the first region surrounds the second region.

3. The organic light-emitting display apparatus of claim 1, wherein a size of the second electrode is substantially the same as that of the second region.

4. The organic light-emitting display apparatus of claim 1, wherein the first regions of at least two of the first electrodes are electrically connected to each other.

5. The organic light-emitting display apparatus of claim 1, wherein at least two of the second electrodes are electrically separated from each other.

6. The organic light-emitting display apparatus of claim 1, wherein the gate electrode comprises:
a first layer including a transparent conductive material which is included in the pixel electrode, and
a second layer including a metal.

7. The organic light-emitting display apparatus of claim 1, wherein the second electrode comprises:
a first layer including the transparent conductive material included in the pixel electrode, and
a second layer including a metal.

8. The organic light-emitting display apparatus of claim 6, wherein the transparent conductive material comprises at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

9. The organic light-emitting display apparatus of claim 1, wherein each of the at least two capacitors further comprises a third electrode disposed on the second electrode.

10. The organic light-emitting display apparatus of claim 9, wherein the third electrode is formed in substantially the same plane as the source and drain electrodes, and comprises the same material as the source and drain electrodes.

11. The organic light-emitting display apparatus of claim 1, wherein the active layer comprises amorphous silicon or polysilicon.

12. The organic light-emitting display apparatus of claim 1, wherein the active layer, the gate electrode, and the source and drain electrodes of the thin film transistor are sequentially disposed on a substrate.

13. The organic light-emitting display apparatus of claim 12, wherein a first insulating layer is disposed between the active layer and the gate electrode, and is directly disposed in a lower portion of the pixel electrode.

14. The organic light-emitting display apparatus of claim 1, wherein the pixel electrode is formed from a material comprising a transparent conductive material, and the opposite electrode is formed from a material comprising a reflective material.

15. A method of manufacturing an organic light-emitting display apparatus, the method comprising:
performing a first mask process in which a semiconductor layer is formed on a substrate and the semiconductor layer is patterned to form an active layer of a thin film transistor and first electrodes of a plurality of capacitors;
performing a second mask process in which a first insulating layer is formed on the resultant structure of the first mask process, and a transparent conductive material and a first metal are sequentially deposited on the first insulating layer and patterned to form a gate electrode of the thin film transistor, second electrodes of the at least two capacitors, and a pixel electrode;
performing a third mask process in which a second insulating layer is formed on the resultant structure of the second mask process, and contact holes for exposing portions of source and the drain regions of the active layer and the pixel electrode are formed;
performing a fourth mask process in which a second metal is deposited on the resultant structure of the third mask process, and the second metal is patterned to form source and drain electrodes, respectively, contacting the source and the drain regions and to remove the first metal and the second metal on the pixel electrode; and
performing a fifth mask process in which a third insulating layer is formed on the resultant structure of the fourth mask process, and the third insulating layer is patterned to expose the pixel electrode.

16. The method of claim 15, wherein after the second mask process is performed, the source and drain regions and a boundary of the first electrodes that do not overlap the second electrodes are doped with ion impurities.

17. The method of claim 16, wherein a wire used to connect at least two of the first electrodes is doped with ion impurities.

18. The method of claim 15, wherein the second electrodes are smaller than the first electrodes.

19. The method of claim 15, wherein the fourth mask process comprises:
a first etching process for removing the second metal, and
a second etching process for removing the first metal.

20. The method of claim 15, wherein in the fourth mask process, the second metal and the first metal are the same material and the first metal and second metal are simultaneously etched.

21. The method of claim 15, wherein the second metal is patterned to further form third electrodes on the second electrodes.

22. The method of claim 15, wherein, after the fifth mask process is performed, a light-emitting layer and an opposite electrode are further formed on the pixel electrode.
